(19) United States
(12) Patent Application Publication
(10) Pub. No.: US 2011/0163415 A1
(43) Pub. Date: Jul. 7, 2011

(54) SEMICONDUCTOR DEVICE AND METHOD FOR MANUFACTURING THE SAME

(75) Inventor: Hyung Jin PARK, Icheon (KR)

(73) Assignee: Hynix Semiconductor Inc., Icheon (KR)

(21) Appl. No.: 12/845,539

(22) Filed: Jul. 28, 2010

(30) Foreign Application Priority Data
Jan. 6, 2010 (KR) 10-2010-0000771

(51) Int. Cl. H01L 29/92; H01L 21/02

(52) U.S. Cl. 257/532; 438/386; 438/396; 257/E21.011; 257/E29.342

(57) ABSTRACT

A method for manufacturing a semiconductor device comprises depositing an absorption barrier layer of a dielectric film on a semiconductor substrate including a bottom electrode contact plug so as to separate the dielectric films between capacitors without having any influence of a bias of the adjacent capacitor, thereby improving a refresh characteristic of cells.

### CROSS-REFERENCE TO RELATED APPLICATION

The priority of Korean patent application No. 10-2010-0000771 filed on Jan. 6, 2010, the disclosure of which is hereby incorporated in its entirety by reference, is claimed.

### BACKGROUND OF THE INVENTION

The present invention relates to a semiconductor device and a method for manufacturing the same.

In the case of semiconductor devices like a DRAM, as the degree of integration increases, the area occupied by the device continues to decrease while a necessary capacitance is required to be maintained or increased. Generally, there are several methods to secure a sufficient cell capacitance in a limited area, these methods include using a high dielectric material as a dielectric film, reducing the thickness of the dielectric film or increasing the effective area of a bottom electrode. The method of using a high dielectric material requires physical and temporal investment like the introduction of new equipment, reliability of the dielectric film and necessity of yield verification and a low temperature condition for a subsequent process. As a result, the method of increasing the effective area of a bottom electrode has been widely used since a previously used dielectric film can be continuously used and a process can be easily performed.

For the method of increasing the effective area of a bottom electrode, there are methods for creating a bottom electrode with a three-dimensional structure (e.g., a cylinder type or a fin type), for growing a Hemi Spherical Grain (HSG) in the bottom electrode and for increasing the height of the bottom electrode. The method of growing the HSG may have disadvantages when a critical dimension (CD) between the bottom electrodes is secured with a given standard. Moreover, the HSG may peel off which results in a bridge between the bottom electrodes. As a result, it is difficult to apply the HSG method in a semiconductor device with a design rule of less than 0.14 μm. In order to improve the cell capacitance, the method of forming the bottom electrode with a three-dimensional structure and increasing the height has been generally used. The widely used method forms the bottom electrode with a cylinder type or a stack type structure.

Specifically, a conventional method for forming a cylinder-type bottom electrode comprises removing a sacrificial insulating film disposed around a bottom electrode and depositing a dielectric film on the upper portion of the bottom electrode. A dielectric material included in the dielectric film is deposited not only on the bottom electrode but also between the adjacent bottom electrodes so that the dielectric material and a top electrode formed on the dielectric material are shared by all cells. When the dielectric material is shared and used, the capacitance (storage capacity) between all bottom electrodes is intervened or distorted.

### BRIEF SUMMARY OF THE INVENTION

Various embodiments of the invention are directed to depositing an absorption barrier layer of a dielectric film on a semiconductor substrate including a bottom electrode contact plug so as to separate the dielectric films between capacitors without having any influence of a bias of the adjacent capacitor, thereby improving a refresh characteristic of cells.

A semiconductor device comprises: an absorption barrier layer formed on a semiconductor substrate including a bottom electrode contact plug; a bottom electrode coupled to the bottom electrode contact plug; and a dielectric film formed on the bottom electrode and separated between the bottom electrodes.

The semiconductor device further comprises an etch stopper layer deposited between the semiconductor substrate and the absorption barrier layer.

The semiconductor device further comprises an amorphous carbon layer and a sacrificial insulating film on the absorption barrier layer.

The semiconductor device further comprises a nitride film for a Nitride Floating Capacitor (NFC) deposited on the sacrificial insulating film.

The absorption barrier layer includes a Tetra-Ethyl-Methyl-Amino (TEMA) material.

According to another embodiment of the present invention, a semiconductor device comprises: a sacrificial insulating film formed on a semiconductor substrate including a bottom electrode contact plug; an absorption barrier layer formed on the resultant surface including the sacrificial insulating film; a bottom electrode coupled to the bottom electrode contact plug; and a dielectric film formed on the bottom electrode and separated between the bottom electrodes.

The semiconductor device further comprises an etch stopper layer deposited between the semiconductor substrate and the sacrificial insulating film.

The absorption barrier layer includes a TEMA material.

The semiconductor device further comprises a nitride film for a NFC deposited between the sacrificial insulating film and the absorption barrier layer.

According to an embodiment of the present invention, a method for manufacturing a semiconductor device comprises: forming an absorption barrier layer on a semiconductor substrate including a bottom electrode contact plug; forming a sacrificial insulating film on the resultant structure including the absorption barrier layer; etching the sacrificial insulating film and the absorption barrier layer until the bottom electrode contact plug is exposed to form a bottom electrode region; forming a bottom electrode in the bottom electrode region; removing the sacrificial insulating film; and forming a dielectric film formed on the bottom electrode and separated between the bottom electrodes.

The method further comprises depositing an etch stopper layer between the semiconductor substrate and the absorption barrier layer.

The method further comprises depositing an amorphous carbon layer between the absorption barrier layer and the sacrificial insulating film.

The absorption barrier layer includes a TEMA material.

The method further comprises depositing a nitride film for a NFC on the sacrificial insulating film.

The sacrificial insulating film includes a Phosphorus Silicate Glass (PSG) film and a Tetra Ethyl Ortho Silicate (TEOS) film.

The removing-the-sacrificial-insulating-film is performed by a dip-out process.

The dielectric film is not formed on the absorption barrier layer in the forming-a-dielectric-film-to-be-separated-from-each-other.

The method further comprises forming a top electrode after forming a dielectric film to be separated from each other.

The forming-a-bottom-electrode-in-the-bottom-electrode-region includes: forming a conductive layer in the bottom electrode region; and performing an etch-back process or a Chemical Mechanical Polishing (CMP) process until the sacrificial insulating film is exposed.

According to another embodiment of the present invention, a method for manufacturing a semiconductor device comprises: forming a sacrificial insulating film on a semiconductor substrate including a bottom electrode contact plug; forming an absorption barrier layer on the sacrificial insulating film; etching the absorption barrier film the absorption barrier layer and the sacrificial insulating film until the bottom electrode contact plug is exposed to form a bottom electrode region; forming a bottom electrode in the bottom electrode region; and forming a dielectric film formed on the bottom electrode and separated between the bottom electrodes.

The method further comprises depositing an etch stopper layer between the semiconductor substrate and the sacrificial insulating film.

The method further comprises depositing a nitride film for a NFC between the sacrificial insulating film and the absorption barrier layer.

The sacrificial insulating film includes a PSG film and a TEOS film.

The forming-a-bottom-electrode-in-the-bottom-electrode-region includes: forming a conductive layer in the bottom electrode region; and performing an etch-back process or a Chemical Mechanical Polishing (CMP) process until the sacrificial insulating film is exposed.

The dielectric film is not formed on the absorption barrier layer in the forming-a-dielectric-film-to-be-separated-from-each-other.

The method further comprises forming a top electrode after forming a dielectric film to be separated from each other.

After forming a top electrode, the method further comprises performing a CMP process on the top electrode to separate the top electrodes.

### BRIEF DESCRIPTION OF THE DRAWINGS

FIGS. 1a to 1f are cross-sectional diagrams illustrating a semiconductor device and a method for manufacturing the same according to an embodiment of the present invention.

FIGS. 2a to 2e are cross-sectional diagrams illustrating a semiconductor device and a method for manufacturing the same according to another embodiment of the present invention.

### DESCRIPTION OF EMBODIMENTS

The present invention will be described in detail with reference to the attached drawings.

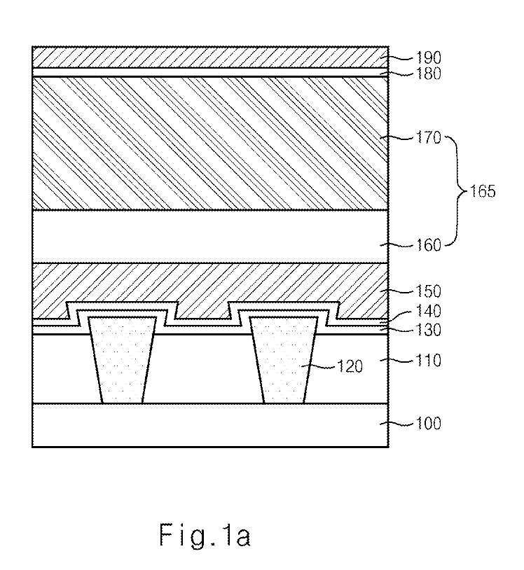

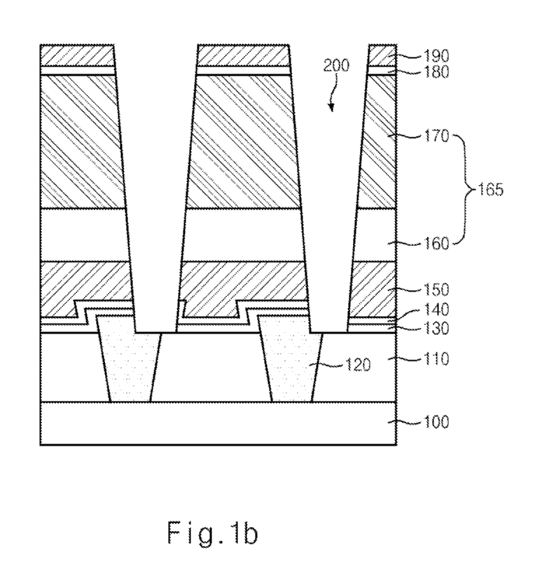

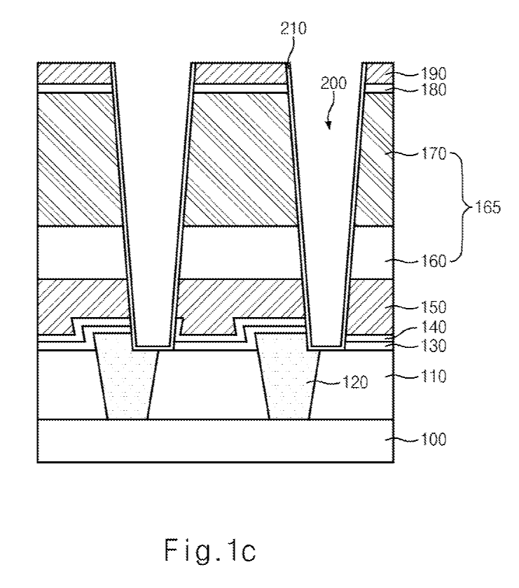

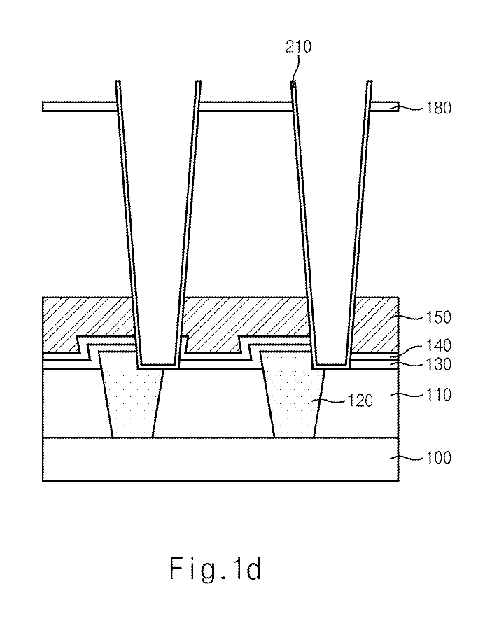

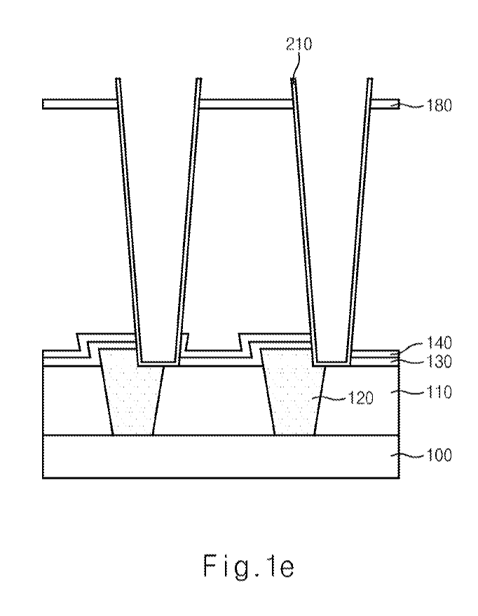

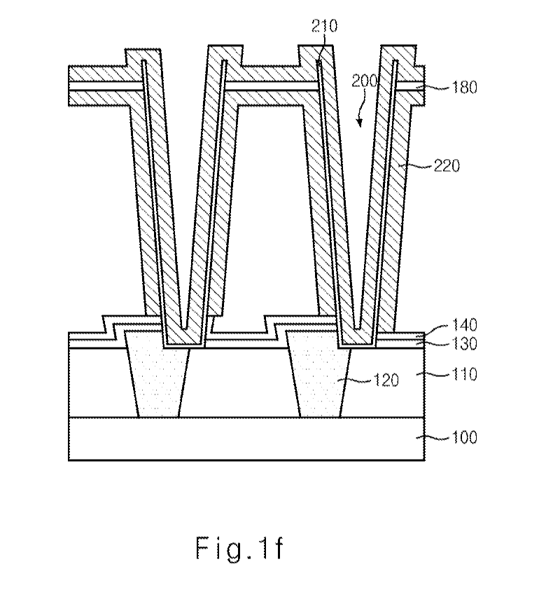

FIGS. 1a to 1f are cross-sectional diagrams illustrating a semiconductor device and a method for manufacturing the same according to an embodiment of the present invention.

Referring to FIG. 1a, an interlayer insulating film 110 is formed on a semiconductor substrate 100. The interlayer insulating film 110 is etched using a bottom electrode contact mask to form a bottom electrode contact region (not shown). A conductive material is buried in the bottom electrode contact region to form a bottom electrode contact 120.

An etch stopper layer 130 is deposited on the interlayer insulating film 110 and the bottom electrode contact 120. The etch stopper layer 130 includes a nitride film.

An absorption barrier layer (or absorption prevention layer) 140 is deposited on the etch stopper layer 130. The absorption barrier layer 140 includes a Tetra-Ethyl-Methyl Amino (TEMA) material. When a dielectric film such as a zirconium dioxide (ZrO₂) is deposited during a subsequent process, the absorption barrier layer 140 inhibits growth or absorption of the dielectric film.

An amorphous carbon layer 150 is deposited on the resulting surface including the absorption barrier layer 140. The amorphous carbon layer 150 can protect an underlying film or an underlying layer because it is insoluble in a HF etch solution used in a subsequent dip out process.

A sacrificial insulating film 165 is formed on the resultant surface including the amorphous carbon layer 150. The sacrificial insulating film 165 includes a Phosphorus Silicate Glass (PSG) film 160 and a Tetra Ethyl Ortho Silicate (TEOS) film 170 which are sequentially deposited.

A nitride film 180 for a Nitride Floating Capacitor (NFC) and an insulating film 190 are sequentially formed on the resultant structure including the sacrificial insulating film 165. The nitride film 180 for a NFC prevents collapse of the bottom electrodes formed in a subsequent process and supports the bottom electrodes.

Referring to FIG. 1b, after a photoresist film is formed on the insulating film 190, the insulating film 190, the nitride film 180 for a NFC, the sacrificial insulating film 165, the amorphous carbon layer 150, the absorption barrier layer 140 and the etch stopper layer 130 are etched until the bottom electrode contact 120 is exposed by using a bottom electrode mask (not shown), thereby forming a first trench 200.

Referring to FIG. 1c, after a conductive layer (not shown) is deposited on the inner surface of the first trench 200, an etch-back or a Chemical Mechanical Polishing (CMP) process is performed until the insulating film 190 is exposed, thereby forming a bottom electrode 210. The conductive layer includes a titanium nitride (TiN) film or a stack structure having a titanium nitride (TiN) film and a tungsten (W) film.

Referring to FIG. 1d, after the bottom electrode 210 is formed, a dip-out process is performed to remove the insulating film 190 and the sacrificial insulating film 165. After the dip-out process, the amorphous carbon layer 150 can prevent the collapse of the bottom electrode because the amorphous carbon layer 150 supports the lower sidewalls of the bottom electrode 210. Also, since the absorption barrier layer 140 and the etch stopper layer 130 are protected by the amorphous carbon layer 150, a bunker defect generated in the lower layers can be prevented.

Referring to FIG. 1e, the amorphous carbon layer 150 is removed with ashing treatment using a plasma process. The plasma process is performed with an O₂ gas.

Referring to FIG. 1f, a dielectric film 220 is deposited on the surface of the bottom electrode 210 by an Atomic Layer Deposition (ALD) process. When the dielectric film 220 is deposited, the absorption barrier layer 140 deposited between the bottom electrodes 210 prevents growth or absorption of the dielectric film 220 between the bottom electrodes 210. This results in the lower portions of the dielectric films 220 to be separated from each other. In an embodiment, the dielectric film 220 is formed on the around the bottom electrodes 210, i.e., provided on both sides of the bottom electrode 210. A conductive material is provided over the dielectric film 220 to define an upper electrode (not shown). The upper electrode may be provided on only within the first trench 220. Alternatively, the conductive material may be formed around the dielectric film 220 in order to increase the surface area and the capacitance of the capacitor being formed.

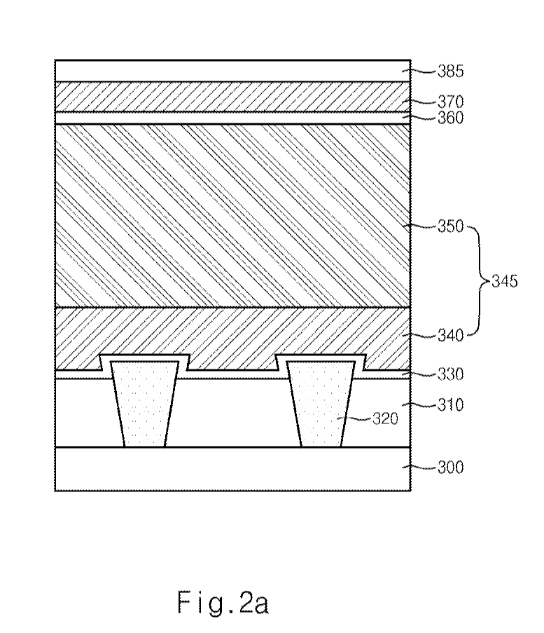

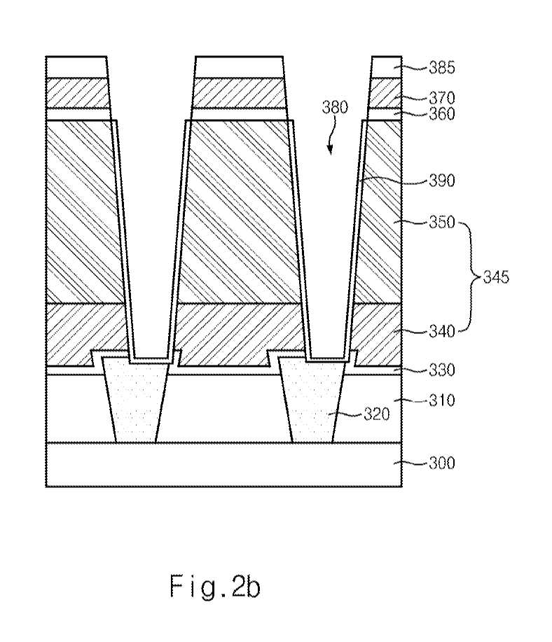

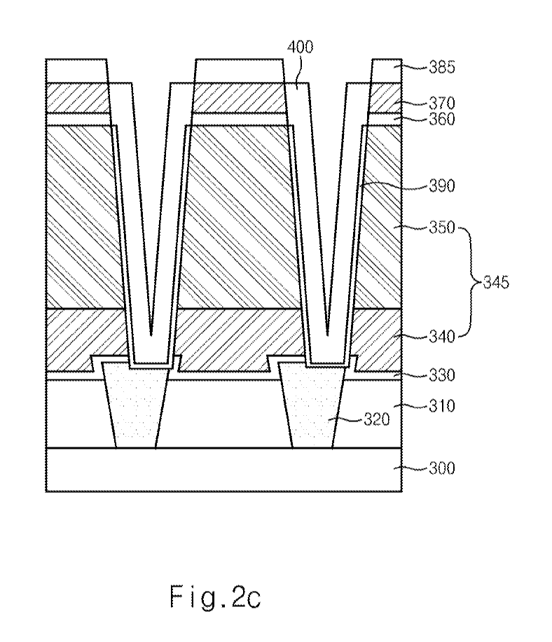

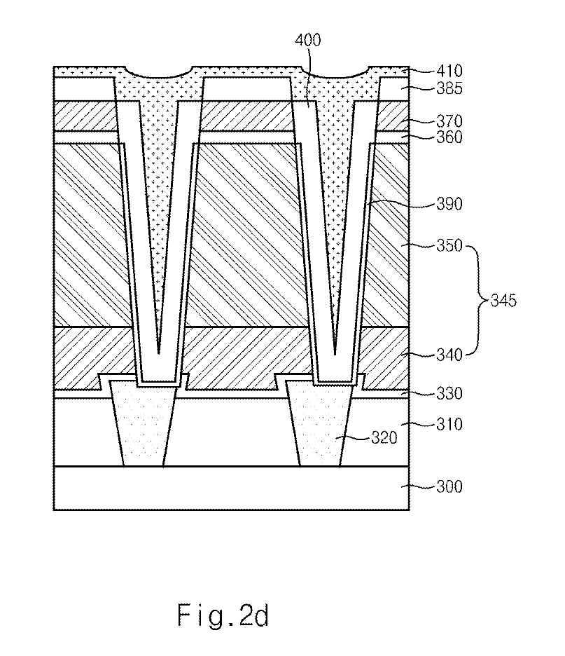

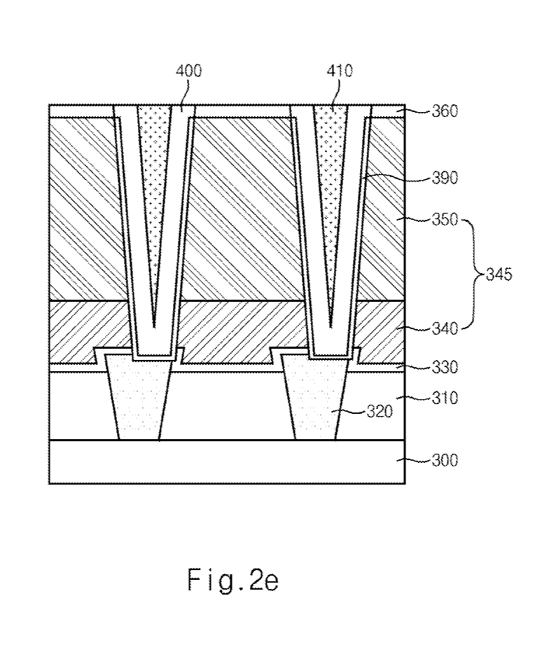

FIGS. 2a to 2e are cross-sectional diagrams illustrating a semiconductor device and a method for manufacturing the same according to another embodiment of the present invention.

Referring to FIG. 2a, an interlayer insulating film 310 is formed on a semiconductor substrate 300. The interlayer insulating film 310 is etched using a bottom electrode contact mask (not shown) to form a bottom electrode contact region (not shown). A conductive material is buried in the bottom electrode contact region to form a bottom electrode contact 320.

An etch stopper layer 330 is deposited on the interlayer insulating film 310 and the bottom electrode contact 320. The etch stopper layer 330 includes a nitride film.

A sacrificial insulating film 345 is formed on the etch barrier film 330. The sacrificial insulating film 345 includes a Phosphorus Silicate Glass (PSG) film 340 and a Tetra Ethyl Ortho Silicate (TEOS) film 350 which are sequentially deposited.

A nitride film 360 for a nitride floating capacitor (NFC), an insulating film 370 and an absorption barrier layer 385 are sequentially formed on the sacrificial insulating film 345. The nitride film 360 for a NFC prevents collapse of the bottom electrodes formed in a subsequent process and supports the bottom electrodes. The absorption barrier layer 385 includes a Tetra-Ethyl-Methyl Amino (TEMA) material. When a dielectric film such as a zirconium dioxide (ZrO₂) is deposited during a subsequent process, the absorption barrier layer 140 is a material for inhibiting growth or absorption of the dielectric film.

Referring to FIG. 2b, after a photoresist film is formed on the absorption barrier layer 385, the absorption barrier layer 385, the insulating film 370, the nitride film 360 for a NFC, the sacrificial insulating film 345 and the etch stopper layer 330 are etched until the bottom electrode contact 320 is exposed using a bottom electrode mask (not shown), thereby forming a second trench 380.

After a conductive layer (not shown) is deposited over the inner surface of the second trench 380, an etch back or a Chemical Mechanical Polishing (CMP) process is performed until the absorption barrier layer 385 or the nitride film 360 is exposed, thereby forming a bottom electrode 390. The conductive layer includes a titanium nitride (TiN) film or a stack structure having a titanium nitride (TiN) film and a tungsten (W) film.

Referring to FIGS. 2c and 2d, a dielectric film 400 and a top electrode 410 are sequentially deposited on the resultant surface including the bottom electrode 390. The dielectric film 400 includes a high-K dielectric material. The high-K dielectric material comprises of nitride, Si₃N₄, ZrO₂, La₂O₃, AlO₂, Ta₂O₅, Gd₂O₃ and a combination thereof. The top electrode 410 includes a titanium nitride (TiN) film or a stack structure having a titanium nitride (TiN) film and a tungsten (W) film. When the dielectric film 400 is deposited, the absorption barrier layer 385 inhibits growth or absorption of the dielectric film 400 such as ZrO₂ so that the dielectric film 400 is not formed on the surface of the exposed absorption barrier layer 385. As a result, the absorption barrier layer 385 has a separate dielectric film structure between the bottom electrodes 390.

Referring to FIG. 2e, a CMP process is performed on the top electrode 410 and the dielectric film 400 until the nitride film 360 for a NFC is exposed, thereby forming a concave-shaped capacitor where the dielectric films 400 are separated.

As described above, the embodiments of the present invention includes depositing an absorption barrier layer over which a dielectric film is prevented from being formed, and thus making the dielectric films self-separated between capacitors with no additional process, thereby improving a refresh characteristic of the cells.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
an absorption prevention layer formed over a semiconductor substrate including first and second contact plugs;
a first capacitor having a first electrode coupled to the first contact plug, a dielectric film formed over the first electrode, and a second electrode formed over the dielectric film; and
a second capacitor having a first electrode coupled to the second contact plug, a dielectric film formed over the first electrode, and a second electrode formed over the dielectric film,
wherein the dielectric film of the first capacitor and the dielectric of the second capacitor are separated from each other.

2. The semiconductor device according to claim 1, further comprising an etch stop layer deposited between the semiconductor substrate and the absorption prevention layer.

3. The semiconductor device according to claim 1, wherein the dielectric film of the first capacitor and the dielectric of the second capacitor are separated from each other at lower portions thereof.

4. The semiconductor device according to claim 1, wherein the first and second capacitors each is defined within a trench, the second electrode being provided entirely within the trench.

5. The semiconductor device according to claim 1, wherein the absorption prevention layer includes Tetra-Ethyl-Methyl-Amino (TEMA) material.

6. A semiconductor device comprising:
a sacrificial insulating film formed on a semiconductor substrate including a bottom electrode contact plug;
an absorption prevention layer formed on the resultant surface including the sacrificial insulating film;
a bottom electrode coupled to the bottom electrode contact plug; and
a dielectric film formed on the bottom electrode and separated between the bottom electrodes.

7. The semiconductor device according to claim 6, further comprising an etch stop layer deposited between the semiconductor substrate and the sacrificial insulating film.

8. The semiconductor device according to claim 6, wherein the absorption prevention layer includes a TEMA material.

9. The semiconductor device according to claim 6, further comprising a nitride film for a NFC deposited between the sacrificial insulating film and the absorption prevention layer.

10. A method for manufacturing a semiconductor device, the method comprising:
forming an absorption prevention layer over a semiconductor substrate including a contact plug;
forming a sacrificial insulating film over the absorption prevention layer;
etching the sacrificial insulating film and the absorption prevention layer until the contact plug is exposed to form a trench;
forming a first electrode over at least an inner surface of the trench;
removing the sacrificial insulating film;
forming a dielectric film formed over the first electrode; and
forming a second electrode over the dielectric film,
wherein the first electrode, the dielectric film, and the second electrode define a capacitor, and
wherein the dielectric film of the capacitor is separated from a dielectric film of an adjacent capacitor.

11. The method according to claim 10, further comprising depositing an etch stop layer between the semiconductor substrate and the absorption prevention layer.

12. The method according to claim 10, further comprising depositing an amorphous carbon layer between the absorption prevention layer and the sacrificial insulating film.

13. The method according to claim 10, wherein the absorption prevention layer includes Tetra-Ethyl-Methyl-Amino (TEMA) material.

14. The method according to claim 10, further comprising depositing a nitride film for a NFC over the sacrificial insulating film.

15. The method according to claim 10, wherein the sacrificial insulating film includes a Phosphorus Silicate Glass (PSG) film and a Tetra Ethyl Ortho Silicate (TEOS) film.

16. The method according to claim 10, wherein the removing-the-sacrificial-insulating-film step is performed by a dip-out process.

17. The method according to claim 10, wherein the dielectric film is not grown on the absorption prevention layer in the forming-a-dielectric-film step.

18. The method according to claim 10, wherein the forming-a-first-electrode step includes:
forming a conductive layer over an inner surface of the trench; and
performing an etch-back process or a Chemical Mechanical Polishing (CMP) process until the sacrificial insulating film is exposed.

19. A method for manufacturing a semiconductor device, the method comprising:
forming a sacrificial insulating film over a semiconductor substrate including a contact plug;
forming an absorption prevention layer over the sacrificial insulating film;
etching the absorption prevention film and the sacrificial insulating film until the contact plug is exposed to form a trench;
forming a first electrode over at least the inner surface of the trench;
forming a dielectric film formed on the first electrode; and
forming a second electrode over the dielectric film,
wherein the first electrode, the dielectric film, and the second electrode define a capacitor, and
wherein the dielectric film of the capacitor is separated from a dielectric film of an adjacent capacitor.

20. The method according to claim 19, further comprising depositing an etch stop layer between the semiconductor substrate and the sacrificial insulating film.

21. The method according to claim 19, further comprising depositing a nitride film for a NFC between the sacrificial insulating film and the absorption prevention layer.

22. The method according to claim 19, wherein the sacrificial insulating film includes a PSG film and a TEOS film.

23. The method according to claim 19, wherein the forming-a-first-electrode step includes:
forming a conductive layer over at least the inner surface of the trench; and
performing an etch-back process or a Chemical Mechanical Polishing (CMP) process until the sacrificial insulating film is exposed.

24. The method according to claim 19, further comprising performing a CMP process on the second electrode to separate the second electrode from a second electrode of an adjacent capacitor.

25. A method for manufacturing a semiconductor device, the method comprising:
forming is first and second trenches on a substrate;
forming first and second bottom storage electrodes within the first and second trenches, respectively;
forming an absorption prevention film between the first and the second bottom storage electrodes; and
forming a dielectric film over the first and the second bottom storage electrodes to form a first dielectric pattern formed over the first bottom storage electrode and a second dielectric pattern formed over the second bottom storage electrode,
wherein the absorption prevention film is configured to inhibit the dielectric film from being formed over the absorption prevention layer, so that the first and the second dielectric patterns do not contact each other.

26. The method according to claim 25, wherein the absorption prevention film connects the first and the second bottom storage electrodes directly or indirectly by interposing an additional pattern.

27. The method according to claim 25, wherein the absorption prevention film is a mask pattern that is used to form the first and second trenches.

28. The method according to claim 25, wherein the dielectric film is formed on first and second sides of each of the first and second bottom storage electrodes.
